(19) United States
(12) Patent Application Publication
(10) Pub. No.: US 2026/0278230 A1
(43) Pub. Date: Sep. 17, 2026

(54) ACCELERATED CIRCUIT DESIGN TEST COVERAGE CLOSURE USING MACHINE-LEARNING BASED CONSTRAINT RANDOMIZATION

(71) Applicants: Advanced Micro Devices, Inc., Santa Clara, CA (US); Xilinx, Inc., San Jose, CA (US)

(72) Inventors: Vijay Palaparthy, Nagpur (IN); Aasham Taneja, Jalandhar (IN); Sayan Mukherjee, Kolkata (IN); Tapodyuti Mandal, Hyderabad (IN); Sridhar Rudraraju, Hyderabad (IN)

(73) Assignees: Advanced Micro Devices, Inc., Santa Clara, CA (US); Xilinx, Inc., San Jose, CA (US)

(21) Appl. No.: 19/076,566

(22) Filed: Mar. 11, 2025

(51) Int. Cl. G06F 30/333; G06F 30/31

(52) U.S. Cl. CPC G06F 30/333; G06F 30/31

(57) ABSTRACT

Accelerated circuit design test coverage closure includes generating, by computer hardware, constraint ranges for input variables for a circuit design based on constraints for the input variables. A first value set for a verification testbench for the circuit design is generated. The first value set includes randomly generated values for the input variables constrained based on the constraint ranges. Whether the first value set is unique is detected by comparing the first value set with training value sets of a training corpus. In response to detecting that the first value set is unique, the first value is classified set by assigning a label selected from a plurality of labels to the first value set and adding the first value set to the training corpus.

A portion of the disclosure of this patent document contains material which is subject to copyright protection. The copyright owner has no objection to the facsimile reproduction by anyone of the patent document or the patent disclosure, as it appears in the Patent and Trademark Office patent file or records but otherwise reserves all copyright rights whatsoever.

### TECHNICAL FIELD

This disclosure relates to verification of circuit designs for integrated circuits (ICs) and, more particularly, to accelerating test coverage closure for circuit designs for ICs using machine learning.

### BACKGROUND

Functional coverage is an important aspect of circuit design used by the semiconductor industry. Functional coverage ensures that when a circuit design such as, for example, a register transfer level (RTL) design, is physically realized as an integrated circuit (IC) and released into the field, the circuit design/IC functions as intended. Functional coverage provides a measure of the particular functions and/or features of the circuit design that have been exercised by tests. In this respect, functional coverage has become a necessary part of the development of every circuit design and/or integrated circuit. Functional coverage typically ensures rigorous review of circuit design testing to achieve 100% coverage.

Presently, functional coverage seeks to test circuit designs by creating a verification testbench and subjecting the circuit design to a variety of different tests referred to as regression testing. This process requires the generation of input data that is fed to the circuit design to drive the testing process. Given the large size of modern circuit designs and the significant number of tests that are conducted to verify a circuit design, the amount of input data necessary is quite large. In the typical case, values for the inputs (e.g., variables) of the circuit design are selected using a random process. With currently available randomized test data generation techniques, there is no guarantee that the same value or set of values will not be generated multiple times (e.g., for multiple tests). This redundancy means that a larger number of test iterations are necessary to generate and test all possible values for a given variable and achieve a desired level of test coverage for the circuit design under test. The iteration count may increase exponentially with the number of elements being considered thereby significantly increasing the time required for verification and increasing the amount of computing resources needed for that testing.

As a simplified example, for a given variable having a range of [0,1], for any two successive randomization calls, values such as (0, 0), (0, 1), (1, 0), and (1, 1) may be generated. It may be seen that out of the different combinations that may be returned as input values for testing the circuit design, only (0, 1) and (1, 0) are without repetition. The values (0, 0) and (1, 1) repeat the same value for the variable in each iteration meaning that the second test iteration is not achieving any greater test coverage. In the case of the (0, 0) and (1, 1) value sets, further test iteration(s) would be required to achieve full test coverage for this particular variable. The problem is only exacerbated for larger numbers of variables and for larger variable ranges.

Generalizing the above example, if a reduced range for a given input variable is of the form [r1:r2] where r2−r1+1=m, then with m randomization trials there will be mm combinations of possible values out of which only!m combinations are desired combinations. The probability of getting all unique values generated in m randomization trials is

$$\frac{! m}{{m}^{m}} .$$

This probability is further reduced as the number of variables increases. The overall probability is the product of the probability of each individual variable. For two random variables a and b, if the reduced range is of the form a->[ar1:ar2]->(ar2−ar1+1)=m1 and b->[br1:br2]->(br2−br1+1)=m2, the probability of generating unique combinations in m*m randomization trials without repetition is

$$\frac{! ( m 1 \times m 2 )}{{( m 1 \times M 2 )}^{( m 1 \times m 2 )}} ,$$

which may be simplified as

$$\frac{! M}{{M}^{M}} ,$$

where M=m1×m2.

### SUMMARY

In one or more examples, a method includes generating, by computer hardware, constraint ranges for input variables for a circuit design based on constraints for the input variables. The method includes generating, by the computer hardware, a first value set for a verification testbench for the circuit design. The first value set includes randomly generated values for the input variables constrained based on the constraint ranges. The method includes detecting, by the computer hardware, whether the first value set is unique by comparing the first value set with training value sets of a training corpus. The method includes, in response to detecting that the first value set is unique, classifying the first value set by assigning a label selected from a plurality of labels to the first value set and adding the first value set to the training corpus.

In one or more examples, a system includes a hardware processor and one or more computer-readable storage mediums having program instructions stored thereon to cause the hardware processor to perform operations. The operations include generating a first value set for a verification testbench for the circuit design. The first value set includes randomly generated values for the input variables constrained based on the constraint ranges. The operations include detecting whether the first value set is unique by comparing the first value set with training value sets of a training corpus. The operations include, in response to detecting that the first value set is unique, classifying the first value set by assigning a label selected from a plurality of labels to the first value set and adding the first value set to the training corpus.

In one or more examples, a computer program product includes one or more computer-readable storage mediums having program instructions stored thereon. The program instructions are executable by computer hardware to cause the computer hardware to initiate operations. The operations include generating a first value set for a verification testbench for the circuit design. The first value set includes randomly generated values for the input variables constrained based on the constraint ranges. The operations include detecting whether the first value set is unique by comparing the first value set with value sets of a training corpus. The operations include, in response to detecting that the first value set is unique, classifying the first value set by assigning a label selected from a plurality of labels to the first value set and adding the first value set to the training corpus.

This Summary section is provided merely to introduce certain concepts and not to identify any key or essential features of the claimed subject matter. Many other features and implementations of the disclosed technology will be apparent from the accompanying drawings and from the following detailed description.

### BRIEF DESCRIPTION OF THE DRAWINGS

The accompanying drawings show one or more implementations of the disclosed technology. The drawings, however, should not be construed to be limiting of the implementations to only the examples shown. Various aspects and advantages will become apparent upon review of the following detailed description and upon reference to the drawings.

FIG. 1 illustrates an example of a verification environment for a circuit design including a machine learning (ML) framework.

FIGS. 2A, 2B, and 2C, taken collectively, illustrate an example method of performing verification testing for a circuit design.

FIG. 3 illustrates an example of a constraint expression tree that may be generated by a constraint engine of the verification environment of FIG. 1.

FIG. 4 illustrates an example of constraint ranges that may be provided to the ML framework of FIG. 1.

FIG. 5 illustrates an example implementation of the ML framework of FIG. 1.

FIG. 6 illustrates an example method of verification of value sets for simulation using the verification environment of FIG. 1.

FIG. 7 illustrates an example of a data processing system for use with the example implementations described herein.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to verification of circuit designs for integrated circuits (ICs) and, more particularly, to accelerating test coverage closure for circuit designs for ICs using machine learning. In accordance with the implementations described within this disclosure, methods, systems, and computer-program products are provided that are capable of generating unique and constrained random data for performing verification testing on circuit designs. The data, as generated, may be used as input data for a verification test bench while performing regression testing on a circuit design under test.

Conventional approaches for generating test input data rely on feedback from a merged coverage database to generate and/or update the parameters necessary to obtain unique and constrained random data. As such, coverage data from prior performed regression testing is used to generate updated test input data for next or future regression testing iterations. This iterative process that relies on regression testing results to generate further unique test data requires significant time and computing resources.

The example implementations described herein provide a computer-based framework capable of automatically generating unique, constrained, and randomized data for use as input to a circuit design under test that is undergoing verification testing. The example implementations are capable of generating data “on the fly,” e.g., in real-time as testing is performed. This data may be generated without any feedback from coverage values of prior regression testing thereby avoiding unnecessary regression testing iterations. In this regard, the testing data may be generated independently of the regression testing itself.

One or more example implementations incorporate a machine learning (ML) architecture capable of generating constrained, randomized test input data significantly faster than conventional approaches. The ability to generate data faster, e.g., in a more computationally efficient manner, means that fewer regression testing iterations and fewer computing resources are required to perform verification testing of a circuit design to achieve a desired amount of test coverage. The increased efficiency may be achieved for both single-point (e.g., generating values for single variable) and for inline (e.g., generating values for a plurality of variables) randomization.

Further aspects of the disclosed technology are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

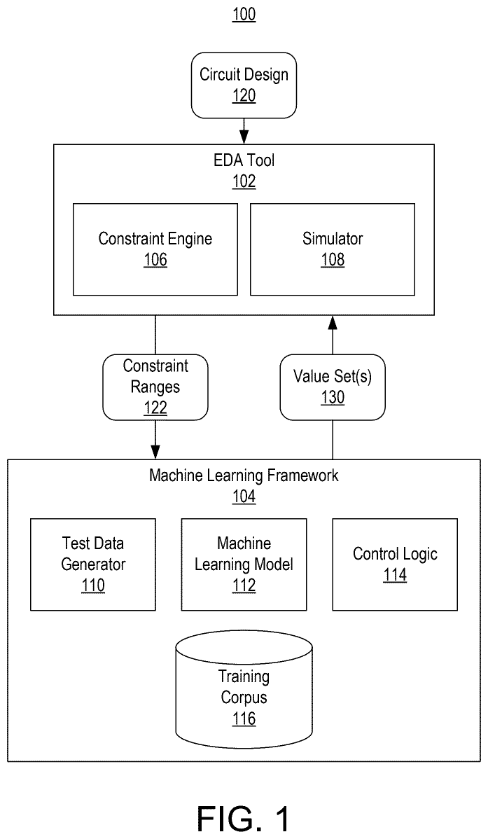

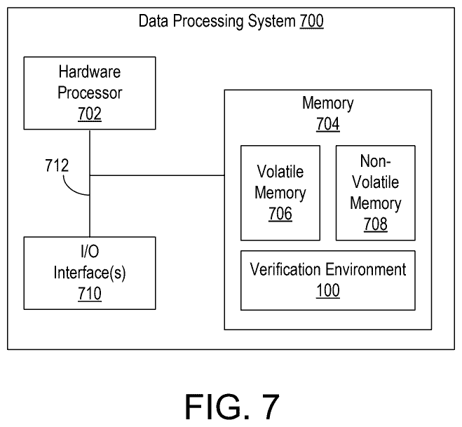

FIG. 1 illustrates an example of a verification environment 100 for a circuit design. Verification environment 100 may be implemented as program instructions that may be executed by a data processing system or a plurality of interconnected, e.g., networked, data processing systems. An example of a data processing system that is capable of executing verification environment 100 is described in connection with FIG. 7.

In the example, verification environment 100 includes an electronic design automation (EDA) tool 102 and a machine learning (ML) framework 104. EDA tool 102 may include a constraint engine 106 and a simulator 108. ML framework 104 may include a test data generator 110, a machine learning (ML) model 112, and control logic 114. ML framework 104 also includes a training corpus 116.

Verification environment 100 is capable of performing regression testing of circuit design 120. Regression testing refers to performing one or more simulations executed by simulator 108 on circuit design 120. In one or more examples, simulator 108 may be implemented as an RTL (register-transfer level) simulator that implements a verification testbench in which circuit design 120 is the “device under test” or “DUT.” Appreciably, simulator 108 also may include components such as a stimulus generator (input driver), a response monitor (output monitor), a clock and reset generator, a comparator capable of comparing simulation output with expected results (scoreboard), and/or a control mechanism to manage the sequence or plurality of tests forming the regression test. The simulations performed by simulator 108 of circuit design 120 may be cycle-accurate simulations capable of providing or outputting sampled values on each clock cycle based on the simulation clock signal(s) provided by the clock generator.

In general, in running the regression test, simulator 108 is capable of supplying circuit design 120 with one or more input test vectors from training corpus 116 for testing. The input test vectors (e.g., the value sets generated using ML framework 104 as described herein) may be pushed to circuit design 120 as input by the input driver for testing. Simulator 108 is capable of capturing output from the regression test of circuit design 120. Based on the output captured from the regression test compared with expected output, the verification testbench is capable of determining whether each individual test of the regression test of circuit design 120 passed or failed.

In general, circuit design 120 receives input signals, where each input signal may be represented within circuit design 120 as an input variable. A test vector refers to a set of one or more values provided to circuit design 120 where each of the values corresponds to one of the input variables. Within this disclosure, a test vector is also referred to as a “value set” in reference to each value provided as an input signal for an input variable of the circuit design. A value set may include one or more values corresponding to one or more respective input variables of the circuit design. It may be observed that a regression test involves submitting a large number of different value sets to the testbench to test circuit design 120.

The example implementations described herein may be used within the context of IEEE-1800 and, more particularly, may be utilized in various verification scenarios that follow and/or comply with the IEEE 1800.2-2020 Universal Verification Methodology Language Reference Manual (UVM). The example implementations, however, may be used in any of a variety of different contexts and are not intended to be limited for use with any one particular verification/simulation environment or standard.

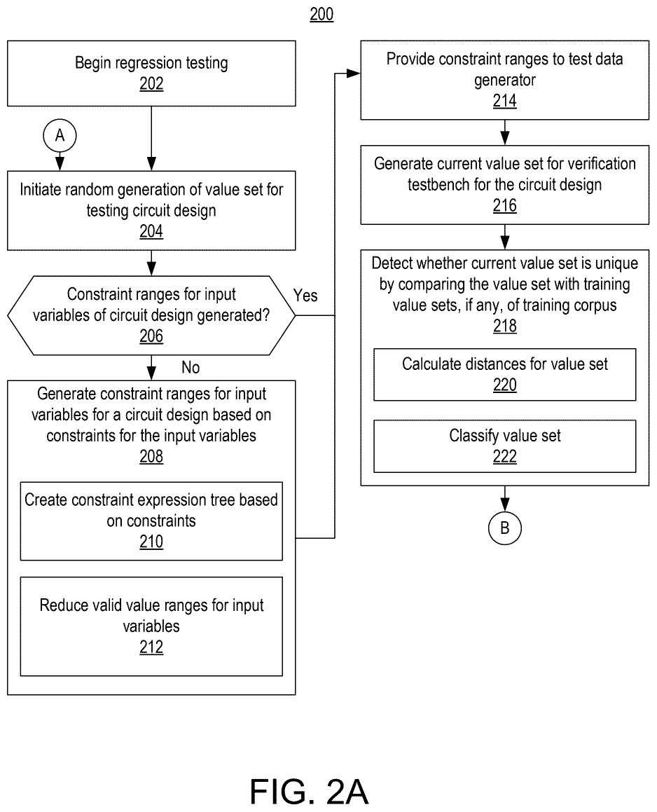

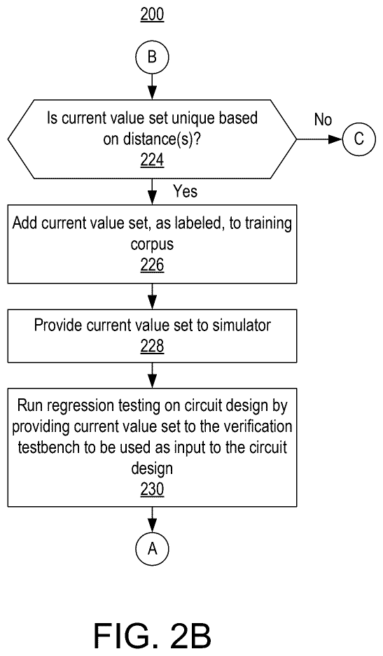

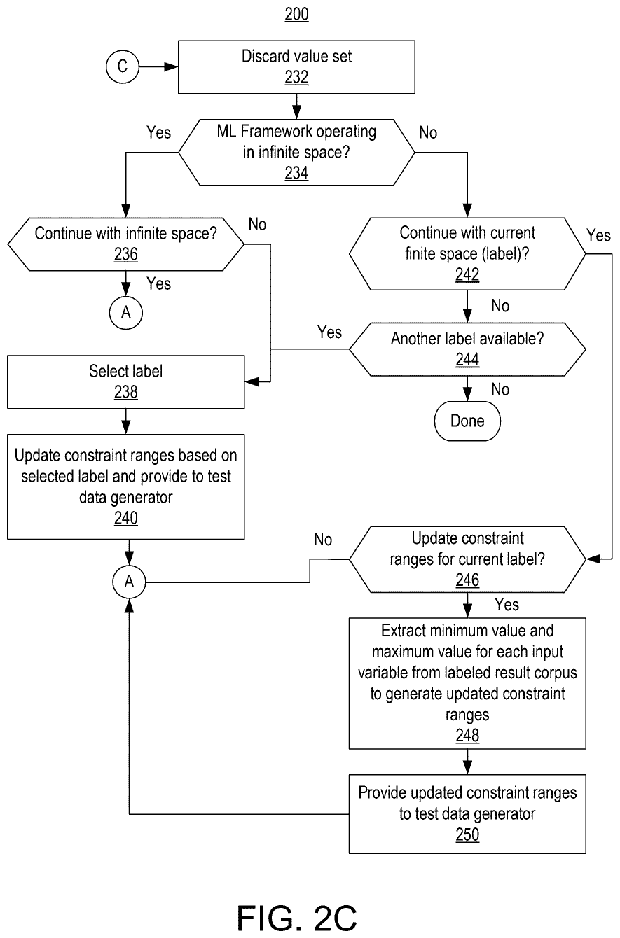

FIGS. 2A, 2B, and 2C, taken collectively, illustrate an example method 200 of performing verification testing for a circuit design. FIGS. 2A, 2B, and 2C may be referred to herein collectively to as FIG. 2. Method 200 may be performed by a data processing system executing verification environment 100 of FIG. 1. Referring to FIGS. 1 and 2 in combination, method 200 may begin in a state where verification environment 100 has received a circuit design 120 for testing. Circuit design 120 may be specified as an RTL description. For example, circuit design 120 may be specified in a hardware description language.

In block 202, verification environment 100 may begin regression testing of circuit design 120. The example implementations described herein are capable of generating input data, e.g., values for input signals for circuit design 120, “on-the-fly.” In other words, the input data may be generated for the regression testing in real-time while regression testing is performed as opposed to having to generate data prior to regression testing and then iterating to generate further input data based on the results of one or more first phases of regression testing (e.g., prior regression testing) to achieve a desired test coverage for circuit design 120.

In block 204, EDA tool 102 is capable of initiating random generation of a value set (e.g., a first value set) for testing circuit design 120. As an example, simulator 108 may initiate this process. In doing so, in block 206, simulator 108 is capable of detecting whether constraint ranges for the input variables of circuit design 120 have been generated (e.g., whether such constraint ranges exist). In response to detecting that constraint ranges for the input variables of circuit design 120 have been generated (e.g., constraint ranges do exist), method 200 continues to block 214. In response to detecting that constraint ranges for the input variables of circuit design 120 have not been generated (e.g., constraint ranges do not exist), method 200 continues to block 208.

In block 208, constraint engine 106 is capable of generating constraint ranges for the input variables of circuit design 120 based on constraints detected within circuit design 120 for the input variables. For example, constraint engine 106 is capable of parsing circuit design 120 to detect constraints, e.g., user-specified constraints, defined for input variables of circuit design 120. In the example, block 208 includes blocks 210 and 212.

The constraint ranges for the input variables may be referred to as the infinite space. The term “infinite space” refers to the constraint range for a given input variable or for each of a plurality of input variables. The term “finite space” refers to a subset of the constraint range of a given input variable or a subset of the constraint range for each of a plurality of input variables. In general, each finite space may be viewed as a subset or window of the larger constraint range or infinite space.

In block 210, constraint engine 106 is capable of creating a constraint expression tree based on the constraints. The constraint expression tree is generated based on constraints detected for the input variables within circuit design 120. For example, constraint engine 106 is capable of extracting the constraints for each input variable of circuit design 120, if such constraint(s) are defined, and adding the constraints to the constraint expression tree.

In block 212, constraint engine 106 is capable of reducing the valid value ranges of the input variables of circuit design 120. For example, constraint engine 106 is capable of traversing the constraint expression tree once generated and enforcing the constraints on the respective input variables. In enforcing the constraints, constraint engine 106 is capable of detecting dependencies among the input variables and interaction between the corresponding constraints. For example, constraint engine 106 is capable of detecting that an input variable, based on a dependency of that input variable with another, will never take on a particular value despite that value being within a range defined by the constraints for the input variable. In this manner, constraint engine 106 is capable of reducing the constraint ranges of the input variables.

In one or more examples, constraint engine 106 is capable of implementing a forward/backward implication on the constraint expression tree to implement blocks 208 and 210. In implementing the forward/backward implication, constraint engine 106 may continue to iterate over the constraint expression tree tracking the constraint range for each input variable in a data structure. Constraint engine 106 may continue to iterate over the constraint expression tree until no reduction of a constraint range for any input variable is achieved. The forward/backward implication is capable of testing combinations and/or exploring the available space of values in compliance with constraints to detect potential violations and update the constraint expression tree according to the results.

Example 1 below illustrates pseudo code illustrating input variables that are defined and applicable constraints from an example circuit design.

Example 1

```
class cls;
rand int a; //range [−2147483648 to 2147483647]
rand int b; //range [−2147483648 to 2147483647]
rand int c; //range [−2147483648 to 2147483647]
rand int d; //range [−2147483648 to 2147483647]
rand int e; //range [−2147483648 to 2147483647]
constraint c {
  a inside {[1:9]};
  b inside {[1:9]};
  c == a+b;
  d inside {[4:8]};
  e inside {[4:8]};
}
endclass
```

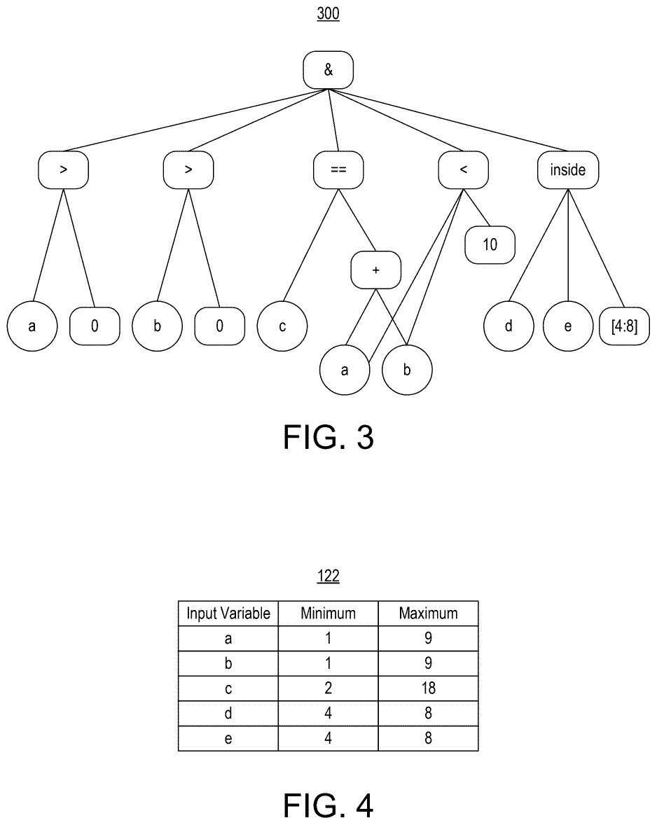

FIG. 3 illustrates an example of a constraint expression tree 300 that may be generated by constraint engine 106. In the example of FIG. 3, the constraint expression tree specifies constraints for variables a, b, c, d, and e. Constraint expression tree 300 specifies that the values for each of variables a and b may be in the range of 1 to 9, that variable c will always be the sum of variables a and b, and that the values for each of variables d and e will be in the range of 4 to 8.

In block 214, EDA tool 102 and, more particularly, constraint engine 106, is capable of providing constraint ranges 122 (e.g., the infinite space) to test data generator 110. FIG. 4 illustrates an example of constraint ranges 122 that may be provided from constraint engine 106 to test data generator 110. The constraint ranges 122, which are valid ranges of the variables a, b, c, d, and e as determined from constraint expression tree 300, are used as bounds in randomly generating values for each of the input variables defined. That is, as simulator 108 initiates a call for the generation of a randomized value for each of the input variables for circuit design 120, test data generator 110 is capable of generating such values in response based on, or as restricted by, the respective constraint ranges for each input variable from constraint ranges 122. The constraint ranges, at least as initially derived from constraint expression tree 300 and as illustrated in FIG. 4 illustrate the infinite space for the input variables.

In block 216, test data generator 110 is capable of generating a value set (e.g., a first or current value set) for the verification testbench for circuit design 120. The value set includes randomly generated values for the input variables constrained based on constraint ranges 122. That is, test data generator 110 may include a random number generator capable of randomly generating a value for each input variable where the value that is generated is within, or constrained by, the defined range for that input variable. The defined input range for each variable is, at least initially specified by constraint ranges 122. In subsequent iterations, the defined input range may be specified by constraint ranges 122 or other updated constraint ranges as described herein in greater detail below.

In block 218, ML framework 104 is capable of detecting whether the current value set generated in block 216 is unique. In one or more examples, ML model 112 is implemented as a K-Nearest Neighbor (KNN) model. As generally known, a KNN model is capable of predicting a label for a given input (e.g., the current value set) based on a detected similarity between the input and training data stored in training corpus 116.

ML model 112 may be configured to use a selected number of labels. A user may specify the number of labels to be used as a configuration parameter of ML model 112. For example, if the number of labels to be used is specified by a user to be 3, the range for each variable from constraint ranges 122 may be divided into 3 labels. Referring to variable a, for example, the range of variable a may be divided into label-1 having a range of 1-3, label-2 having a range of 4-6, and label-3 having a range of 7-9. Each of the other ranges of the variables would be similarly divided albeit subject to the minimum and maximum of each respective variable from constraint ranges 122. In this example, the ranges as defined by a minimum and a maximum for each label for each variable have no overlap (e.g., the ranges are evenly distributed). In some cases, overlap in ranges of the labels may exist such as where the number of labels is greater than the data range of a variable. As an example, 3 labels for a variable range of 0-1 may result in label-1 having a value of 0 and each of label-1 and label-2 having or sharing the value of 1.

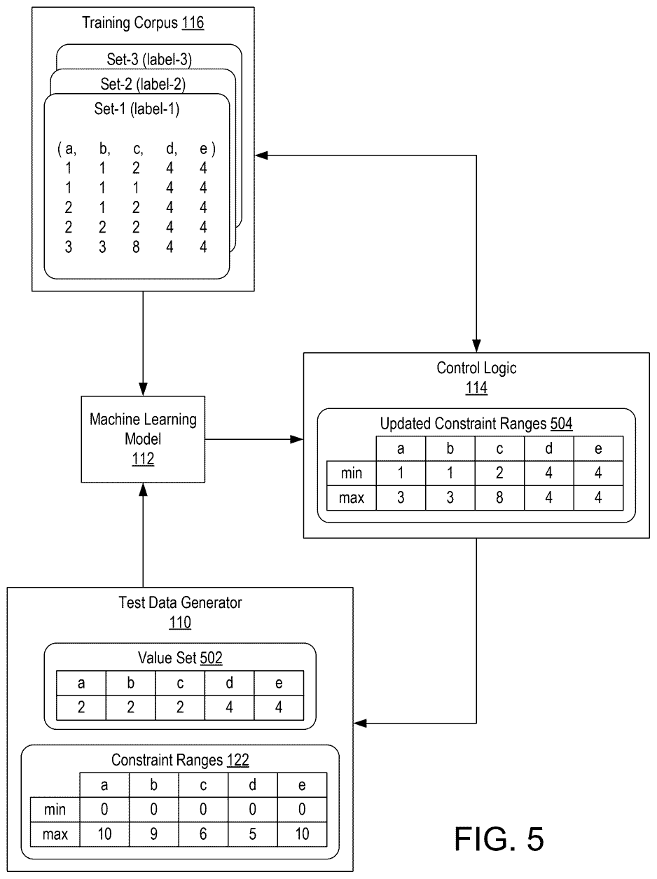

The number of training data sets included/created in training corpus 116 depends on the number of labels used by ML model 112. There is a one-to-one relationship between labels and training data sets. FIG. 5 illustrates an example implementation of ML framework 104. In the example of FIG. 5, the number of labels used by ML model 112 is 3. As such, training corpus 116 includes 3 different training data sets, e.g., one for each label, and shown as set-1, set-2, and set-3, which correspond to labels label-1, label-2, and label-3, respectively.

ML framework 104 is capable of comparing the current value set with training value sets stored in training corpus 116. A value set that is generated by test data generator 110 that is found to be unique, e.g., a value set with a combination of values that has not yet been generated for a given regression test of a circuit design and is not present within training corpus 116, is stored in training corpus 116. Initially, as method 200 begins, training corpus 116 is empty. In this empty state, training corpus 116 may be considered to include a starting training value set of all zero values that may be used for purposes of evaluating the first current value set generated. As unique value sets are generated, each such value set is added to training corpus 116 and provided to simulator 108 for regression testing. As unique value sets are generated and added to training corpus 116, the corpus of training data is built over time as method 200 iterates.

In implementing block 218, ML model 112 is capable of operating on the current value set generated in block 216. In the example, block 218 includes blocks 220 and 222. In block 220, ML model 112 is capable of calculating distances of the current value set. In calculating distances as discussed, ML model 112 receives two inputs that include the current value set and the corpus of training value sets. The KNN model is capable of calculating a distance between the current value set and each training value set within training corpus 116.

The KNN model may use any of a variety of different distance metrics to measure the distances. In one or more implementations, the distances may be calculated as Euclidean distances. The k nearest neighbors may be output along with the calculated distance between the value set and each of the k nearest neighbors. In this example, k may be an integer value specified as a system parameter. The label of each of the k nearest neighbors also may be output. Accordingly, ML model 112 is capable of calculating a distance between the current value set and each training value set that is a member of training corpus 116. In the case where training corpus 116 is initially empty, a training value set of all zero values may be used in calculating distance with the current value set.

In block 222, ML model 112 classifies the current value set. The KNN model is capable of classifying the value set by predicting a label for the current value set and assigning the label, as predicted, to the current value set. The label assigned to the current value set may be the label of the training value set of training corpus 116 that is the shortest/smallest distance from the current value set generated in block 216. In some cases, for example k may be set to a value of 1. In other examples, a voting mechanism may be used where the KNN model selects the label of the majority of the k nearest neighbors (e.g., where k is an integer greater than 1) of the current value set and assigns the selected label to the current value set. In the case where training corpus 116 is initially empty, ML model 112 is capable of assigning a label to the current value set based on the aforementioned label and range subdivisions (e.g., assigning a label having constraint ranges that most closely match the current value set).

In block 224, control logic 114 is capable of determining whether the value set is unique based on the distances provided by ML model 112. For example, the current value set is unique as compared to training value sets of training corpus 116 when the distances calculated for the k nearest neighbors (or the closest nearest neighbor as the case may be) have all non-zero distances. A current value set that is a duplicate of a training value set stored in training corpus 116 will have a zero distance within the distances calculated. As the KNN model is capable of outputting the nearest neighbors, a zero valued distance will be included in the results in the event that the current value set is a duplicate of a training value set stored as part of training corpus 116. Appreciably, while training corpus 116 is empty, e.g., has no value sets stored therein, the distance calculated for the current value set will be non-zero as a zero valued training value set may be used in that case to compute distance to the current value set. In another example, the KNN model may detect that training corpus 116 is empty and, in response to that condition, generate a non-zero distance. Accordingly, in block 224, in response to control logic 114 detecting that the value set is unique, method 200 continues to block 226. In response to control logic 114 determining that the value set is not unique, method 200 continues to block 232.

Continuing with block 226 in the case where the value set is determined to be unique, control logic 114 adds the current value set, as labeled, to training corpus 116. Control logic 114 adds the current value set to the data set of training corpus 116 having the same label assigned thereto. In general, each label corresponds to, or defines, a different finite space. In this regard, the set of possible labels predicted by ML model 112 may be formed of the entire set of finite spaces. The current value set, once added to training corpus 116, becomes a training value set to which later generated “current” value sets are compared resulting in a growing number of unique data sets stored in training corpus 116.

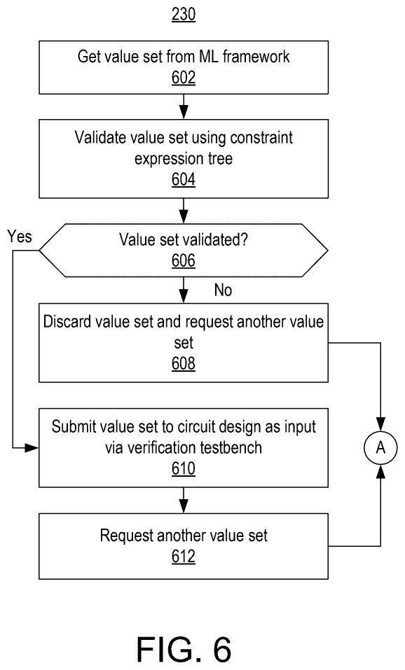

In block 228, the value set, e.g., illustrated as value set(s) 130 in FIG. 1, is provided to simulator 108. In block 230, EDA tool 102 is capable of running regression testing on circuit design 120 by providing the current value set to the verification test bench to be used as input to circuit design 120. Further details regarding block 230 and the use of the value set(s) 130 by EDA tool 102 after receipt from ML framework 104 are described in connection with FIG. 6. After block 230, method 200 may continue to block 204 to generate further value sets for regression testing.

For purposes of illustration, in the example of FIG. 5, through a plurality of iterations of method 200, 5 different value sets have been generated and added to training corpus 116 which are illustrated in set-1, where each row is a different training value set. As shown, each training value set in set-1 is unique. Through continued operation of method 200, further value sets may generated and included within the other sets, i.e., set-2 and/or set-3.

Continuing with block 232 in the case where the current value set is not unique (e.g., is determined to be a copy or duplicate of a training value set stored in training corpus 116 due to the existence of a zero valued distance), different processing is performed. For example, in block 232, the value set may be discarded. More particularly, the value set, being a duplicate, is not added to training corpus 116.

The subsequent processing illustrated in FIG. 2 (e.g., in FIG. 2C) is provided for purposes of illustration and not limitation. The disclosed technology contemplates other decision flows that are also described hereinbelow following the discussion of FIG. 2 that contemplate the generation of updated and/or different constraint ranges under different conditions or circumstances than described in connection with FIG. 2.

In block 234, control logic 114 determines whether ML framework 104 is operating in the infinite space. ML framework 104 operates in the infinite space while the current constraint ranges in effect for ML framework 104 are for the infinite space as opposed to constraint ranges for, or corresponding to, a particular label. In this example, using constraint ranges 122 shown in FIG. 5, the constraint ranges are for the infinite space which are the constraint ranges determined initially from constraint expression tree 300 as the values generated are unconstrained by label-specific ranges or considerations.

In response to determining that ML framework 104 is operating in the infinite space, method 200 continues to block 236. In block 236, control logic 114 detects whether operation of ML framework 104 should continue operating in the infinite space. The determination of whether to continue operating in the infinite space may be based on one or more conditions such as whether a limit on the number of iterations performed (number of seeds or value sets randomly generated) in the infinite space has been attained, whether a limit on the number of instances in which a duplicate value set was generated in the infinite space has been reached, or a combination of these conditions. In response to a determination that operation in the infinite space should continue (e.g., the conditions have not been met to change to a finite space), method 200 can continue and loop back to block 204. In response to a determination that operation in the infinite space should not continue (e.g., the limit for the number of iterations and/or the limit for duplicate value sets that have been generated for the infinite space has/have been reached), method 200 can continue to block 238.

In block 238, control logic 114 selects a label used by ML model 112 (e.g., label-0). In block 240, control logic 114 generates updated constraint ranges based on the selected label and provides the updated constraint ranges (e.g., the constraint ranges for the selected label) to test data generator 110. After block 240, the method may loop back to block 204 to continue generating value sets for regression testing. In block 240, the updated constraint ranges may be the constraint ranges initially specified for the selected label. For example, in the case of label-1, the updated constraint ranges for variable a may be 1-3.

By providing updated constraint ranges to test data generator 110, operation of test data generator 110 is modified in that the behavior of random number generation performed by test data generator 110 will differ from prior iterations owing to the updated constraint ranges being enforced. This makes it more likely that test data generator 110 will generate a value set that is unique and may be used for verification testing.

Continuing with block 242 in the case where ML framework is operating in a finite space, control logic 114 detects whether operation of ML framework 104 should continue operating in the current finite space (in the current label). In some iterations of method 200, ML framework 104 may have transitioned to operating in a particular finite space. The determination of whether to continue operating in the current finite space may be based on one or more conditions. The conditions may be the same as or similar to those described in connection with block 236 albeit applied to the particular finite space in which ML model 112 is currently operating.

For example, the conditions may include whether a limit on the number of iterations performed (number of seeds or value sets randomly generated) in the current finite space has been attained, whether a limit on the number of instances in which a duplicate value set was generated in the current finite space has been reached, or a combination of these conditions. In response to a determination that operation in the current finite space should continue (e.g., the conditions have not been met to change to a different finite space), method 200 can continue to block 246. In response to a determination that operation in the current finite space should not continue (e.g., the limit for the number of iterations and/or the limit for duplicate value sets that have been generated for the current finite space has/have been reached), method 200 can continue to block 244. In the example, it should be appreciated that the limits applied/used in block 242 may differ from those applied/used in block 236.

Continuing with block 244, control logic 114 is capable of determining whether another label is available. Control logic 114 determines whether another label is available for which method 200 has not yet iterated to generate value sets. In response to detecting that no further labels are available, method 200 may end. In response to detecting that one or more labels are available, method 200 continues to block 238 where a next or available is selected. After block 238, method 200 can proceed to block 240 and to 204 as previously discussed.

Continuing with block 246, in the case where the current finite space (e.g., label) will continue to be used, a determination may be made by control logic 114 as to whether the constraint ranges for the current label should be updated (or further updated as the case may be). The determination as to whether to update or further update the constraint ranges for the current finite space may be based on one or more conditions. The conditions may be the same as or similar to those described in connection with block 242. For example, the conditions may include whether a limit on the number of iterations performed (number of seeds or value sets randomly generated) in the current finite space has been attained, whether a limit on the number of instances in which a duplicate value set was generated in the current finite space has been reached, or a combination of these conditions. The particular limits applied in block 246 may be the same as those of block 242 or may differ. In response to a determination the constraint ranges for the current finite space need to be updated, method 200 can proceed to block 204 to continue processing. In response to determining that the constraint ranges for the current finite space should be updated (e.g., the condition(s) have been met), method 200 may continue to block 248.

In block 248, updated constraint ranges are generated. The updated constraint ranges pertain to a particular label, e.g., the current label. In block 248, control logic 114 is capable of extracting a minimum value and a maximum value for each input variable from the data set of the current label to generate updated constraint ranges. As the value sets stored in training corpus 116 are labeled, the extraction of the minimum value and the maximum value for each input variable may be performed using only the value sets having a same label as the current label. The maximum and minimum value for each input variable are used as updated constraint ranges.

In block 250, the updated constraint ranges are provided to test data generator 110. By providing updated constraint ranges to test data generator 110, operation of test data generator 110 is modified in that the behavior of test data generator 110 in generating random values will differ from prior iterations owing to the updated constraint ranges being enforced. This makes it more likely that test data generator 110 will generate a value set that is unique and may be used for verification testing. After block 250, method 200 may loop back to block 204 to continue generating further value sets.

For purposes of illustration, consider the following example with reference to FIG. 5. In the example of FIG. 5, test data generator 110 has received constraint ranges 122 from EDA tool 102. Test data generator 110 may also receive a request from simulator 108 for a unique value set for purposes of regression testing of circuit design 120. Accordingly, test data generator 110 is capable of randomly generating a value set based on constraint ranges 122.

During a first iteration of method 200, test data generator 110 generates a value set of [1, 1, 2, 4, 4] for input variables a, b, c, d, and e. This value set is added to data set “set-1” of training corpus 116 and is labeled as label-1 as training corpus 116 initially includes no other data and the calculated distance will be non-zero. During the next 4 iterations, value sets of [1, 1, 1, 4, 4], [2, 1, 2, 4, 4], [2, 2, 2, 4, 4], and [3, 3, 8, 4, 4] are randomly generated. Each value set is added to training corpus 116 as each has all or only non-zero distances and is unique as compared to the growing set of training value sets in training corpus 116.

In the case where test data generator 110 generates value set 502 as the current value set which includes values [2, 2, 2, 4, 4], it may be seen that this is a duplicate of a training value set within training corpus 116 (e.g., is a duplicate of a previously generated value set that was added to training corpus 116). In this case, value set 502 will have a distance of 0. In this example, if the conditions for transitioning to a finite space are met, control logic 114 will select a label for use and use the constraint ranges as the updated constraint ranges for test data generator 110. For example, if label-0 is selected, the constraint ranges for label-0 will be used. In this example, constraint ranges for variables a, b, c, d, and be may be (0:3), (0:3), (0:2), (0:1), and (0:4), respectively. The particular ranges may vary based on the logic used to subdivide each respective infinite range by the number of labels.

Continuing with the example, value set 502 may be discarded. If a different label is to be used for a next iteration, the updated constraint ranges will be for the newly selected label. If the path from block 246 to block 248 is taken, for example, control logic 114 generates updated constraint ranges based on the minimum and the maximum of the respective values of the data set in training corpus 116 for the current label. For purposes of illustration, if the current label is label-1, control logic 114 generates updated constraint ranges 504 corresponding to the value sets in set-1 which are provided to test data generator 110 for use in generating a next value set.

The example of FIG. 5 illustrates that in cases where a duplicate value set or test vector is generated, such value set is not provided to simulator 108 and, as such, simulation time is not expended. This saves considerable runtime and computing resources allowing for achieving greater test coverage in less time than other conventional regression testing techniques.

The example of FIG. 5 is illustrative of another feature of verification environment 100. In cases where a user may wish to perform limited testing on circuit design 120 or otherwise restrict the range of values for the input variables to a particular finite space or label as opposed to the infinite space, the user may specify or include a label with the request for a unique value set. For example, a user may re-run a portion of a regression test for circuit design 120 that uses only a limited subset of values for the input variables. This allows the user to re-run the regression testing using only a desired or targeted subset of the range of values for each input variable corresponding to a particular label. That is, the regression testing, or a portion thereof, may be re-run using only value sets of the labeled result corpus having the label specified by the user input.

In that case, in response to receiving a label as part of a request, rather than relying on constraint ranges corresponding to the infinite space as obtained from the constraint expression tree previously described, ML framework 104, in response to the request, may begin using the constraint range for the particular label (e.g., finite space) specified by the user as part of the request. This allows the user to perform more focused testing and may be useful in cases where the user wishes to test particular value ranges for input variables as opposed to implementing a complete regression test over the full range of possible values for the input variables as defined by the constraint expression tree.

FIG. 6 illustrates an example implementation of block 230 of FIG. 2 (i.e., of FIG. 2B). As discussed, in block 230 regression testing on circuit design 120 is run by providing the value set to the verification testbench to be used as input to circuit design 120. It may be the case that one or more additional verification checks may be performed on the value set received from ML framework 104 prior to submitting the value set to the verification testbench.

For example, in block 602, simulator 108 receives the value set from ML framework 104. In block 604, simulator 108 is capable of validating the value set using the constraint expression tree. For example, simulator 108 is capable of evaluating the values of the value set by ensuring that, when using the values, the constraint expression tree evaluates to true. A true result means that the value set has been successfully validated (e.g., the value set is valid or specifies valid values for the input variables given the constraints). A false result means that the value set was not successfully validated (e.g., the value set is invalid or specifies one or more values that are not valid values for the input variables given the constraints). In block 606, simulator 108 determines whether the value set has been validated based on the result of running the value set through the constraint expression tree. In response to the value set being successfully validated, the method continues to block 610. In response to the value set being found to be invalid, the method continues to block 608 where simulator 108 discards the value set and requests another value set from ML framework 104 and, more particularly, from test data generator 110.

In block 610, in response to the value set being found valid, the value set is submitted to the circuit design as input within the verification testbench. In block 612, another value set may be requested to continue regression testing. Appreciably, if a stopping condition is encountered, the method may end. In any case, after block 608 or block 612, the method may loop back to block 204 to continue processing.

The example of FIG. 6 ensures that values of the value set to be submitted to the verification testbench comply with the constraint ranges. In limited cases, for example, one or more values for input variables may be out of range or a constraint range may not be fully reduced and/or be otherwise inaccurate. The example method of FIG. 6 ensures that such a value set is discarded.

The example implementations described herein reduce the number of iterations needed to generate test input data for a circuit design compared to conventional approaches. While the examples provided have been simplified for purposes of illustration, one skilled in the art will appreciate that the input test vector for a circuit design may include a large number of values and that generating a sufficient quantity of input test vectors to achieve a desired amount of test coverage (e.g., generate at least a minimum number of different possible values for each input variable and/or each possible value for each input variable) for a circuit design may require significant time and computational resources. The example implementations are capable of converging to a corpus of test input data with unique value sets to achieve greater coverage in significantly less time than using conventional techniques. In some cases, the example implementations may achieve a desired level of test coverage in approximately one-third the time of test data generation techniques that iterate based on prior regression test results.

For example, conventional techniques for generating test vectors may only achieve coverage of approximately 9%, 17%, and 21% for 1,000 seeds (iterations), 2,000 seeds, and 3,000 seeds respectively. In using the example implementations described herein that incorporate ML framework 104, coverage of approximately 20%, 29%, and 48% may be achieved for 1,000 seeds, 2,000 seeds, and 3,000 seeds, respectively demonstrating a significant improvement in regression test coverage.

In one or more other example implementations, different decision making and/or conditions may be imposed on ML framework 104 as to when and/or how to generate updated constraint ranges. In some examples, the particular label that is selected for use as the current label may be the label that is predicted by ML model 112 for a current value set in cases where the current value set is unique and/or is not unique. In some examples, the limits/thresholds defining the conditions for transitioning between the infinite space and finite spaces, between finite spaces, and/or to generate updated constraint ranges as illustrated in block 248 may be user specified values and/or conditions. These limits/threshold may be adjusted higher or lower. In some cases, for example, the limits may be set to one such that the occurrence of a first duplicate value set will cause the system to transition from the global space to a finite space (which may be the finite space of the duplicate value set), select the constraint ranges of a particular label as the updated value set, and/or update the constraint ranges of a selected value set as described in block 248.

FIG. 7 illustrates an example of a data processing system 700. As used herein, “data processing system” refers to one or more hardware systems capable of processing data. Each hardware system may include one or more hardware processors and memory.

Data processing system 700 includes a hardware processor 702. Hardware processor 702 may be implemented as one or more hardware processors. Hardware processor 702 may be implemented as one or more circuits capable of executing computer-readable program instructions (program instructions). The circuit(s) may comprise integrated circuits (ICs) or may be embedded within an IC. In one or more examples, hardware processor 702 may be embodied as a central processing unit (CPU). Hardware processor 702 may include one or more cores, for example, where each core is capable of executing computer-readable program instructions. Hardware processor 702 may be implemented using any of a variety of architectures such as, for example, a complex instruction set computer architecture (CISC), a reduced instruction set computer architecture (RISC), a vector processing architecture, or other known architectures. For example, a hardware processor may be implemented using an x86 architecture (e.g., IA-32, IA-64), a Power Architecture, as an ARM processor, or the like.

Data processing system 700 can include memory 704. Memory 704 may be embodied as one or more computer-readable storage mediums. Memory 704 may include a volatile memory 706 and a non-volatile memory 708. Volatile memory 706 may be embodied as random-access memory (RAM) and may include cache memory. Volatile memory 706 may be referred to as “runtime memory.” Non-volatile memory 708 may include a non-volatile magnetic medium and/or a solid-state medium (typically called a “hard drive”). Non-volatile memory 708 also may include one or more disk drives capable of reading from and writing to various types of removable, non-volatile mediums such as a removable, non-volatile magnetic disk (e.g., a “floppy disk”) and/or a removable, non-volatile optical disk such as a CD-ROM, DVD-ROM or other optical media.

Memory 704 is capable of storing program instructions and/or data such that hardware processor 702 is capable of executing the program instructions to perform one or more operations as described within this disclosure. For example, the program instructions can include an operating system, one or more application programs, other program code, and program data that may be embodied as verification environment 100 or different portions thereof (e.g., EDA tool 102 and/or ML framework 104) of FIG. 1. Hardware processor 702, in executing the computer-readable program instructions, is capable of performing the various operations described herein that are attributable to a computer.

Data processing system 700 may include one or more Input/Output (I/O) interfaces 710. I/O interface(s) 710 allow data processing system 700 to communicate with one or more external devices and/or communicate over one or more networks such as a local area network (LAN), a wide area network (WAN), and/or a public network (e.g., the Internet). Examples of I/O interfaces 710 may include, but are not limited to, network cards, modems, network adapters (wired and/or wireless), hardware controllers, etc. Examples of external devices also may include devices that allow a user to interact with data processing system 700 (e.g., a display, a keyboard, and/or a pointing device) and/or other devices such as accelerator card.

Bus 712 represents one or more of any of a variety of communication bus structures. By way of example, and not limitation, bus 712 may be implemented as a Peripheral Component Interconnect Express (PCIe) bus. Bus 712 couples to each of hardware processor 702, memory 704, and I/O interface(s) 710 through respective interface circuitry thereby allowing the devices to communicate. Bus 712 may represent a plurality of buses that may be interconnected and/or hierarchically organized.

Data processing system 700 is only one example implementation. Data processing system 700 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

The example of FIG. 7 is not intended to suggest any limitation as to the scope of use or functionality of example implementations described herein. Data processing system 700 is an example of computer hardware that is capable of performing the various operations described within this disclosure. In this regard, data processing system 700 may include fewer components than shown or additional components not illustrated in FIG. 7 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

In one or more examples, EDA tool 102 is capable of performing an implementation flow on circuit design 120 (e.g., performing synthesis, placement, routing, and/or configuration data/bitstream generation). The resulting circuit design, as processed through the implementation flow may be physically realized in or as an IC. As discussed, the example implementations described herein facilitate faster convergence of circuit design verification and may result in greater quality-of-result (e.g., fewer errors and/or faults) in the physically realized IC.

The terminology used herein is for the purpose of describing particular examples only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the term “approximately” means nearly correct or exact, close in value or amount but not precise. For example, the term “approximately” may mean that the recited characteristic, parameter, or value is within a predetermined amount of the exact characteristic, parameter, or value.

As defined herein, the terms “at least one,” “one or more,” and “and/or,” are open-ended expressions that are both conjunctive and disjunctive in operation unless explicitly stated otherwise.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of a computer-readable storage medium or two or more computer-readable storage mediums. A non-exhaustive list of examples of a computer-readable storage medium include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a double-data rate synchronous dynamic RAM memory (DDR SDRAM or “DDR”), a portable compact disc read-only memory (CD-ROM), a digital versatile disk (DVD), a memory stick, a floppy disk, or the like.

As defined herein, the terms “in response to” and “responsive to” mean responding or reacting readily to an action or event. Thus, if a second action is performed “in response to” or “responsive to” a first action, there is a causal relationship between an occurrence of the first action and an occurrence of the second action. The term “responsive to” indicates the causal relationship. In some cases, other terms such as “if,” “when,” or “upon” are used and also convey a causal relationship.

As defined herein, the term “user” refers to a human being.

As defined herein, the term “real-time” means a level of processing responsiveness that a user or system senses as sufficiently immediate for a particular process or determination to be made, or that enables the processor to keep up with some external process.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a controller, and a Graphics Processing Unit (GPU).

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc., may be used herein to describe various elements. These elements should not be limited by these terms, as these terms are only used to distinguish one element from another unless stated otherwise or the context clearly indicates otherwise.

A computer program product may include a computer-readable storage medium (or mediums) having computer-readable program instructions thereon for causing a processor to carry out aspects of the implementations described herein. Within this disclosure, the terms “program code,” “program instructions,” and “computer-readable program instructions” are used interchangeably. Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives program instructions from the network and forwards the computer-readable program instructions for storage in a computer-readable storage medium within the respective computing/processing device.

Program instructions for carrying out operations for the implementations described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Program instructions may include state-setting data. The program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the program instructions by utilizing state information of the program instructions to personalize the electronic circuitry, in order to perform aspects of the implementations described herein.

Certain aspects of the implementations are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by program instructions, e.g., program code.

These program instructions may be provided to a processor of a computer, special-purpose computer, or other programmable data processing apparatus to produce a machine, such that the program instructions, which execute via the processor of the computer or other programmable data processing apparatus, create means for implementing the functions/acts specified in the flowchart and/or block diagram block or blocks. These program instructions may also be stored in a computer-readable storage medium that can direct a computer, a programmable data processing apparatus, and/or other devices to function in a particular manner, such that the computer-readable storage medium having program instructions stored therein comprises an article of manufacture including program instructions which implement aspects of the operations specified in the flowchart and/or block diagram block or blocks.

The program instructions may also be loaded onto a computer, other programmable data processing apparatus, or other device to cause a series of operations to be performed on the computer, other programmable apparatus or other device to produce a computer implemented process, such that the program instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the implementations. In this regard, each block in the flowchart or block diagrams may represent a module, segment, or portion of instructions, which comprises one or more program instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and program instructions.

The descriptions of the various implementations of the disclosed technology have been presented for purposes of illustration, but are not intended to be exhaustive or limited to the examples disclosed. Many modifications and variations will be apparent to those of ordinary skill in the art without departing from the scope and spirit of the described examples. The terminology used herein was chosen to best explain the principles of the examples, the practical application or technical improvement over technologies found in the marketplace, or to enable others of ordinary skill in the art to understand the examples disclosed herein.

What is claimed is:

1. A method, comprising:
generating, by computer hardware, constraint ranges for input variables for a circuit design based on constraints for the input variables;
generating, by the computer hardware, a first value set for a verification testbench for the circuit design, wherein the first value set includes randomly generated values for the input variables constrained based on the constraint ranges;
detecting, by the computer hardware, whether the first value set is unique by comparing the first value set with training value sets of a training corpus; and
in response to detecting that the first value set is unique, classifying the first value set by assigning a label selected from a plurality of labels to the first value set and adding the first value set to the training corpus.

2. The method of claim 1, further comprising:
running regression testing on the circuit design by providing the first value set to the verification testbench to be used as input to the circuit design.

3. The method of claim 2, further comprising:
receiving a user input specifying a selected label of the plurality of labels; and
in response to the user input, re-running the regression testing using only training value sets assigned the selected label.

4. The method of claim 1, wherein the detecting whether the first value set is unique comprises:
calculating a distance between the first value set and each training value set of the training corpus;
wherein the first value set is designated as unique in response to each distance calculated being non-zero or in response to detecting that the training corpus is empty.

5. The method of claim 1, wherein the detecting whether the first value set is unique comprises:
processing the first value set using a K-Nearest Neighbor (KNN) model to generate distances between the first value set and the training value sets of the training corpus;
wherein the first value set is designated as unique in response to each distance calculated being non-zero or in response to detecting that the training corpus is empty.

6. The method of claim 1, further comprising:
detecting that a second value set is not unique by processing the second value set using a K-Nearest Neighbor (KNN) model to generate distances between the second value set and the training value sets of the training corpus;
wherein the second value set is designated as not unique in response to at least one distance calculated being zero.

7. The method of claim 6, further comprising:
in response to the second value set being designated as not unique, extracting updated constraint ranges for the input variables from the training corpus; and
generating a further value set for the verification testbench for the circuit design, wherein the further value set includes randomly generated values for the input variables constrained based on the updated constraint ranges.

8. A system, comprising:
a hardware processor; and
one or more computer-readable storage mediums having program instructions stored thereon to cause the hardware processor to perform operations comprising:
generating constraint ranges for input variables for a circuit design based on constraints for the input variables;
generating a first value set for a verification testbench for the circuit design, wherein the first value set includes randomly generated values for the input variables constrained based on the constraint ranges;
detecting whether the first value set is unique by comparing the first value set with training value sets of a training corpus; and
in response to detecting that the first value set is unique, classifying the first value set by assigning a label selected from a plurality of labels to the first value set and adding the first value set to the training corpus.

9. The system of claim 8, wherein the operations further comprise:
running regression testing on the circuit design by providing the first value set to the verification testbench to be used as input to the circuit design.

10. The system of claim 9, wherein the operations further comprise:
receiving a user input specifying a selected label from the plurality of labels; and
in response to the user input, re-running the regression testing using only training value sets assigned the selected label.

11. The system of claim 8, wherein the detecting whether the first value set is unique comprises:
calculating a distance between the first value set and each training value set of the training corpus;
wherein the first value set is designated as unique in response to each distance calculated being non-zero or in response to detecting that the training corpus is empty.

12. The system of claim 8, wherein the detecting whether the first value set is unique comprises:
processing the first value set using a K-Nearest Neighbor (KNN) model to generate distances between the first value set and the training value sets of the training corpus;
wherein the first value set is designated as unique in response to each distance calculated being non-zero or in response to detecting that the training corpus is empty.

13. The system of claim 8, wherein the operations further comprise:
detecting that a second value set is not unique by processing the second value set using a K-Nearest Neighbor (KNN) model to generate distances between the second value set and the training value sets of the training corpus;
wherein the second value set is designated as not unique in response to at least one distance calculated being zero.

14. The system of claim 13, wherein the operations further comprise:
in response to the second value set being designated as not unique, extracting updated constraint ranges for the input variables from the training corpus; and
generating a further value set for the verification testbench for the circuit design, wherein the further value set includes randomly generated values for the input variables constrained based on the updated constraint ranges.

15. A computer program product comprising:
one or more computer-readable storage mediums having program instructions stored thereon, wherein the program instructions are executable by computer hardware to cause the computer hardware to initiate operations comprising:
generating constraint ranges for input variables for a circuit design based on constraints for the input variables;
generating a first value set for a verification testbench for the circuit design, wherein the first value set includes randomly generated values for the input variables constrained based on the constraint ranges;
detecting whether the first value set is unique by comparing the first value set with training value sets of a training corpus; and
in response to detecting that the first value set is unique, classifying the first value set by assigning a label selected from a plurality of labels to the first value set and adding the first value set to the training corpus.

16. The computer program product of claim 15, wherein the operations further comprise:
running regression testing on the circuit design by providing the first value set to the verification testbench to be used as input to the circuit design.

17. The computer program product of claim 16, wherein the operations further comprise:
receiving a user input specifying a selected label from the plurality of label; and
in response to the user input, re-running the regression testing using only training value sets assigned the selected label.

18. The computer program product of claim 15, wherein the detecting whether the first value set is unique comprises:
processing the first value set using a K-Nearest Neighbor (KNN) model to generate distances between the first value set and the training value sets of the training corpus;
wherein the first value set is designated as unique in response to each distance calculated being non-zero or in response to detecting that the training corpus is empty.

19. The computer program product of claim 15, wherein the operations further comprise:
detecting that a second value set is not unique by processing the second value set using a K-Nearest Neighbor (KNN) model to generate distances between the second value set and the training value sets of the training corpus;
wherein the second value set is designated as not unique in response to at least one distance calculated being zero.

20. The computer program product of claim 19, wherein the operations further comprise:
in response to the second value set being designated as not unique, extracting updated constraint ranges for the input variables from the training corpus; and
generating a further value set for the verification testbench for the circuit design, wherein the further value set includes randomly generated values for the input variables constrained based on the updated constraint ranges.
